(19) United States
(12) Patent Application Publication
(10) Pub. No.: US 2014/0083902 A1
(43) Pub. Date: Mar. 27, 2014

(54) PACKAGE STRUCTURE FOR SUBSTRATE STORAGE CONTAINER

(71) Applicant: GUDENG PRECISION INDUSTRIAL CO., LTD., New Taipei City (TW)

(72) Inventors: CHI-TE HUANG, TAOYUAN COUNTY (TW); KO-SHENG TSUI, NEW TAIPEI CITY (TW)

(73) Assignee: Gudeng Precision Industrial Co., Ltd., New Taipei City (TW)

(21) Appl. No.: 13/719,443

(22) Filed: Dec. 19, 2012

(30) Foreign Application Priority Data
Sep. 27, 2012 (TW) 101218682

(51) Int. Cl. H01L 21/677

(52) U.S. Cl. CPC H01L 21/677
USPC 206/710

(57) ABSTRACT

A package structure used to load substrate storage containers for convenience of transportation is revealed. The package structure includes a package box and at least one buffer pad. The buffer pad is disposed in the package box and used for loading a substrate storage container. The density of the buffer pad is smaller than 70 kg/m³. The buffer pad not only separates the package box from the substrate storage container but also absorbs vibration from outside of the package box so as to prevent the vibration from being transmitted to the substrate storage container completely. The amount of vibration that has an impact on the substrate storage container is reduced.

### BACKGROUND OF THE INVENTION

1. Fields of the invention

The present invention relates to a package structure, especially to a package structure for substrate storage containers.

2. Descriptions of Related Art

Generally, the production cost of wafers and integrated circuit is quite expensive. Thus very careful management is required during transportation and packaging. The wafers are packaged by means of a substrate storage container. While using transport vehicles to take delivery of the substrate storage container, the substrate storage container is wrapped by packaging materials such as hard materials. Yet during the transportation process, high frequency vibration is very common in transport vehicles. The vibration at high frequency level is transmitted to the substrate storage container in the packaging materials through a contact surface between the packaging materials and the transport vehicles to make wafers in the substrate storage container rotate. Thus friction between the rotating wafers and internal components of the substrate storage container occurs and a plurality of contaminating particles is produced in the substrate storage container. Therefore the yield rate of semiconductor components is reduced.

In order to solve the above problem, there is a need to provide a novel package structure for substrate storage containers that reduces vibration transmitted to the substrate storage container and prevents substrates inside the substrate storage container from rotating. Thus no contaminating particles are produced due to friction between the rotating substrates and internal components of the substrate storage container.

### SUMMARY OF THE INVENTION

Therefore it is a primary object of the present invention to provide a package structure used for substrate storage containers. The package structure includes at least one buffer pad that separates a package box from a substrate storage container for preventing vibration from outside of the package box being transmitted to the substrate storage container completely. Thus rotation of at least substrate stored in the substrate storage container caused by vibration of the substrate storage container is further avoided. Without rotation, no friction occurs between the substrate and components inside the substrate storage container and no contaminating particles are produced due to the friction. Therefore the yield rate of semiconductor components is improved.

In order to achieve the above object, a package structure used for substrate storage containers of the present invention includes a package box and at least one buffer pad. The package box consists of an opening and a receiving space communicating with each other. The buffer pad is arranged at the package box and located in the receiving space for receiving a substrate storage container. The density of the buffer pad is below 70 kg/m³.

A package structure used for substrate storage containers of the present invention includes a package box and at least one buffer pad. The package box consists of an opening and a receiving space communicating with each other. The buffer pad is arranged at the package box and located in the receiving space for receiving a substrate storage container. The buffer pad further has a filling space for receiving a fluid therein.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing showing an embodiment according to the present invention;

FIG. 2 is a schematic drawing showing an embodiment in use according to the present invention;

FIG. 3 is a schematic drawing showing another embodiment according to the present invention;

FIG. 4 is a schematic drawing showing a further embodiment according to the present invention;

FIG. 5 is a schematic drawing showing a further embodiment according to the present invention;

FIG. 6 is a schematic drawing showing a further embodiment according to the present invention;

FIG. 7 is a schematic drawing showing a further embodiment according to the present invention;

FIG. 8 is a schematic drawing showing a further embodiment according to the present invention;

FIG. 9 is a schematic drawing showing a further embodiment according to the present invention;

FIG. 10 is a schematic drawing showing a further embodiment according to the present invention.

### DETAILED DESCRIPTION OF THE PREFERRED EMBODIMENT

A conventional substrate storage container is mounted in a package box and the package box with the substrate storage container is transported by different vehicles. During transportation, vibration generated has impact on the package box and the vibration is transmitted to the substrate storage container inside the package box. Thus at least one substrate in the substrate storage container is rotated and friction occurs between the substrate and components inside the substrate storage container. Therefore a plurality of contaminating particles is produced in the substrate storage container. The present invention provides a package structure applied to substrate storage containers for solving the problems mentioned above.

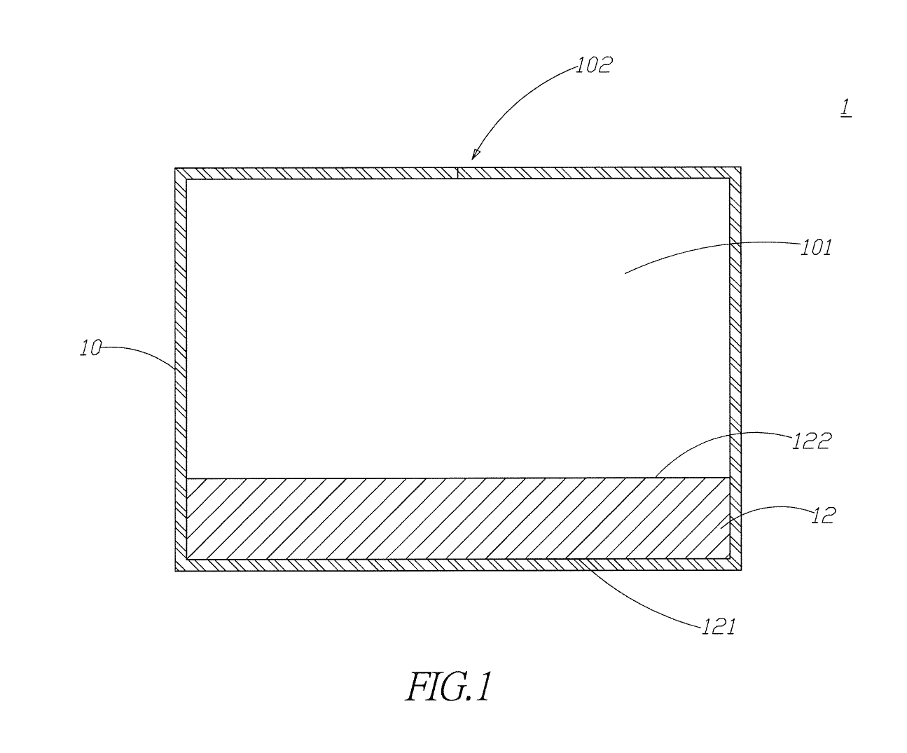

Refer to FIG. 1, a package structure 1 of the present invention includes a package box 10 and a buffer pad 12. The package box 10 consists of a receiving space 101 and an opening 102 communicating with the receiving space 101. The buffer pad is disposed on the bottom of the package box 10 and is located in the receiving space 101. The buffer pad 12 is composed of a first surface 121 and a second surface 122 corresponding to each other. When the buffer pad 12 is arranged at the bottom of the package box 10, the first surface 121 of the buffer pad 12 is in contact with the bottom of the package box 10. The density of the buffer pad 12 is smaller than 70 kg/m³. In this embodiment, the opening 102 is located on the top of the package box 10 to form an up-opened package box 10. Of course, the opening 102 can also be disposed on one side of the package box 10 and communicating with the receiving space so as to form a side-opened package box 10.

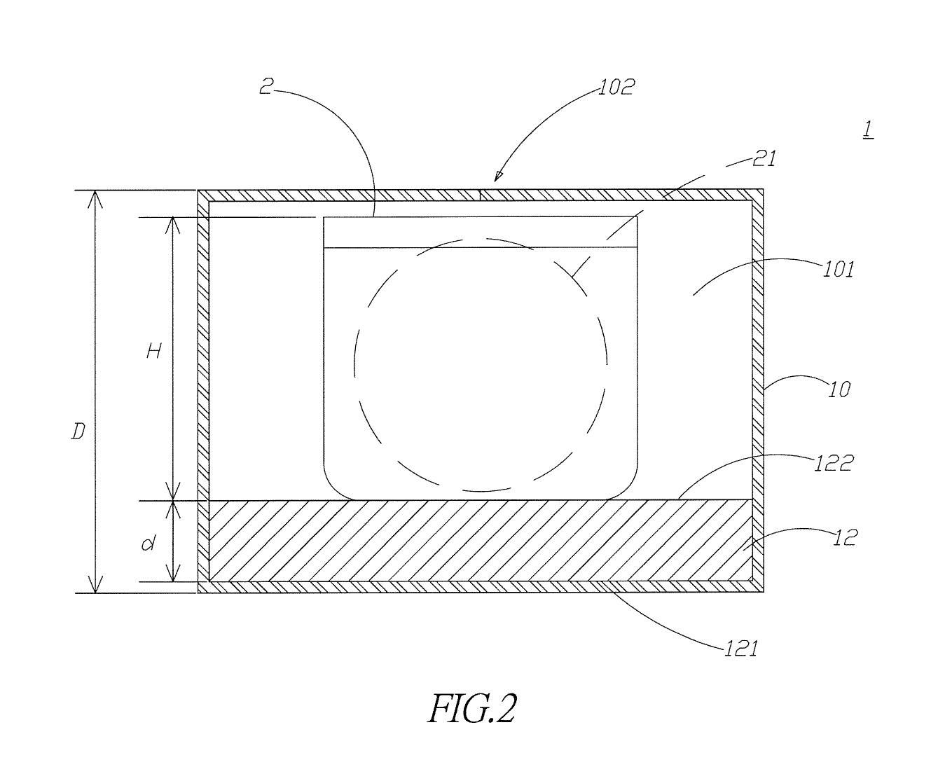

As shown in FIG. 2, while using the package structure 1 to pack a substrate storage container 2, the substrate storage container 2 is set into the receiving space 101 of the package box 10 of the package structure 1 through the opening 102 of the package box 10 of the package structure 1 and is disposed on the second surface 122 of the buffer pad 12. Then the opening 102 of the package box 10 is sealed for convenient transportation of the package structure 1 with the substrate storage container 2 therein. The substrate storage container 2 has received at least one substrate 21 therein. In this embodiment, the substrate storage container 2 is a front opening unified pod (FOUP) in which a plurality of silicon wafers (equal to the substrate 21 mentioned above) is held therein. Each substrate 21 is perpendicular to the second surface 122 of the buffer pad 12.

The buffer pad 12 is a soft pad. In this embodiment, the buffer pad 12 is made from solid materials. The density of the buffer pad 12 is smaller than 70 kg/m³. Thus the buffer pad 12 can support the substrate storage container 2. That means the buffer pad 12 will not collapse due to the overweight of the substrate storage container 2. Moreover, during transportation of the package structure 1 for the substrate storage container 2, high frequency vibration from the transport vehicles is transmitted to the inner space of the package structure 1 through a surface of the package structure 1 in contact with the transport vehicle (mainly the bottom of the package structure 1).

However, the buffer pad 12 separates the substrate storage container 2 from the package box 10 so that the substrate storage container 2 is not contacted with the package box 10 directly. Thus vibration generated outside the package structure 1 will not be directly transmitted to the substrate storage container 2. The contact between the buffer pad 12 and the package box 10 or the contact between the buffer pad 12 and the substrate storage container 2 is not hard contact. Thus the vibration generated outside the package structure 1 will not be transmitted to the substrate storage container 2 completely through the buffer pad 12. That means the buffer pad 12 absorbs vibration transmitted from the outside of the package structure 1 and reduces the amount of the vibration transmitted to the substrate storage container 2. This prevents at least one substrate 21 in the substrate storage container 2 from rotating and avoids friction between internal components of the substrate storage container 2 and the rotating substrate 21. Thus the amount of the contaminating particles produced due to rotation of the substrate 21 during the transportation is reduced significantly.

The thickness of the buffer pad 12 also has impact on the amount of the vibration transmitted from the outside of the package structure 1 to the substrate storage container 2. For example, the larger the thickness d of the buffer pad 12, the longer the pathway of the vibration being transmitted from the outside of the package structure 1 to the substrate storage container 2. Thus the amount of the vibration reaching the substrate storage container 2 is reduced. In this embodiment, the maximum thickness d of the buffer pad 12 is equal to the difference between the depth D of the package box 10 and the vertical height H of the substrate storage container 2. Moreover, the thickness d of the buffer pad 12 is determined according to the vertical height H of the substrate storage container 2. The ratio of the vertical height H of the substrate storage container 2 to the thickness d of the buffer pad 12 is ranging from 1 to 50. For example, the minimum thickness d of the buffer pad 12 is about 9.7 mm when the vertical height H of the substrate storage container 2 is 486 mm.

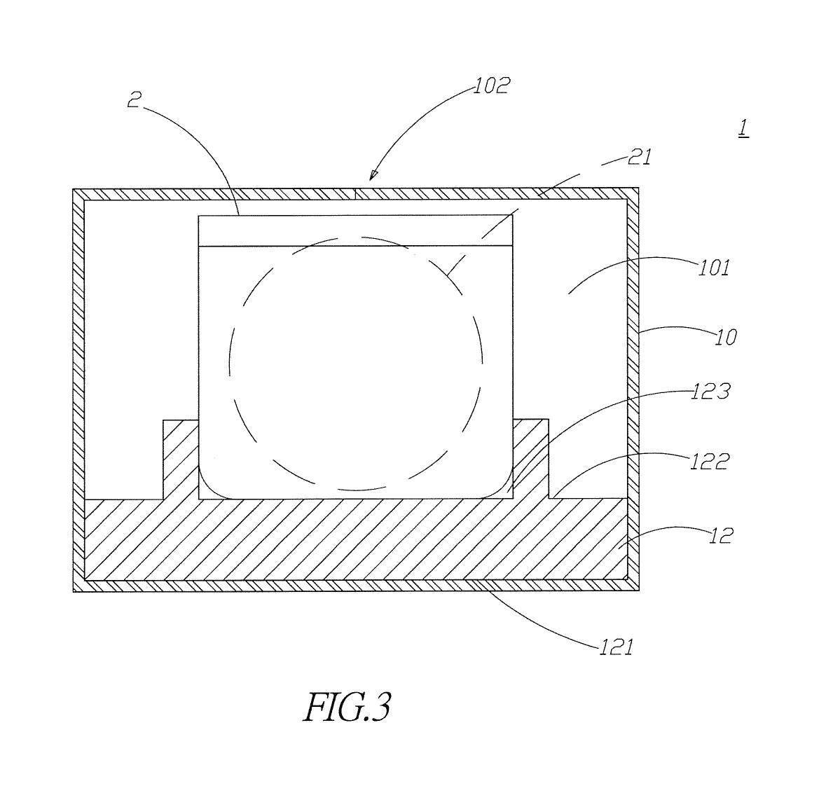

Refer to FIG. 3, another embodiment of the present invention is revealed. As shown in the figure, the difference between this embodiment and the first embodiment is in that a second surface 122 of a buffer pad 12 in this embodiment includes a receiving slot 123. When a substrate storage container 2 is mounted in the receiving slot 123, side walls of the receiving slot 123 cover the periphery of the substrate storage container 2. This not only allows the substrate storage container 2 to be fixed on the second surface 122 of the buffer pad 12 but also prevents the substrate storage container 2 from moving on the second surface 122 of the buffer pad 12 during the transportation. Moreover, the contact between the periphery of the substrate storage container 2 and the package box 10 is also avoided. The design further prevents the vibration being transmitted from the outside of the package structure 1 to the substrate storage container 2.

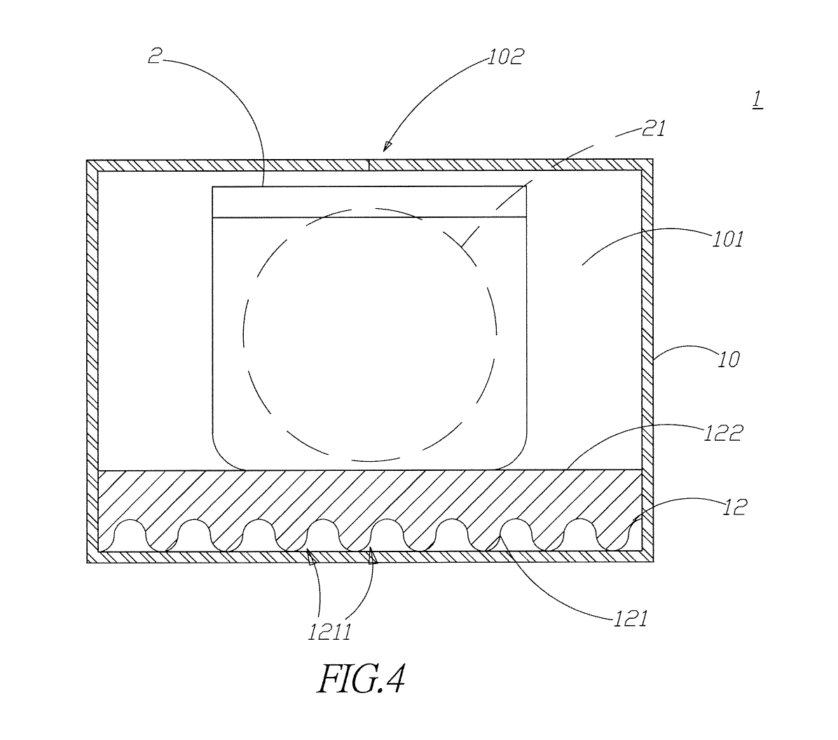

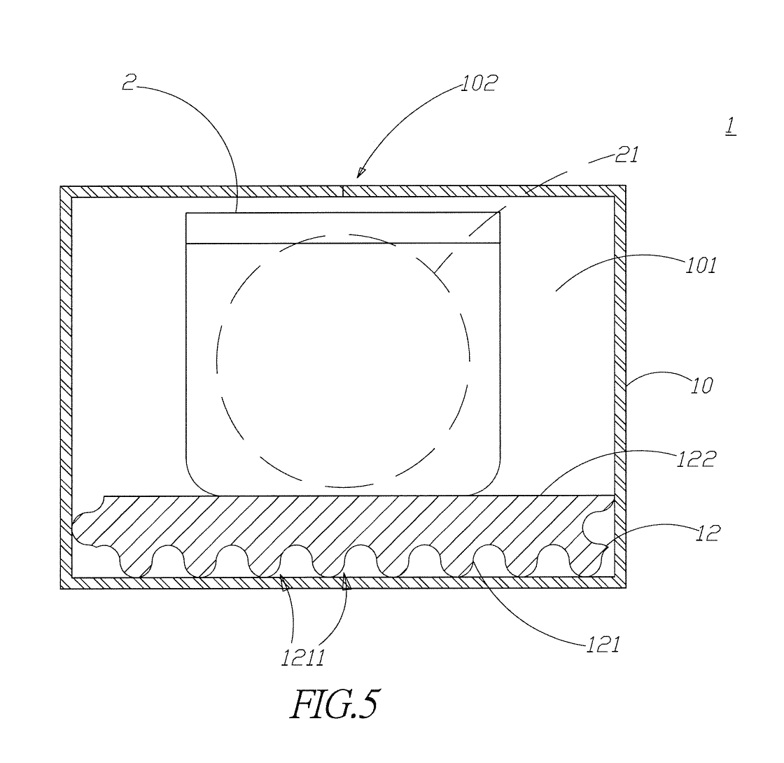

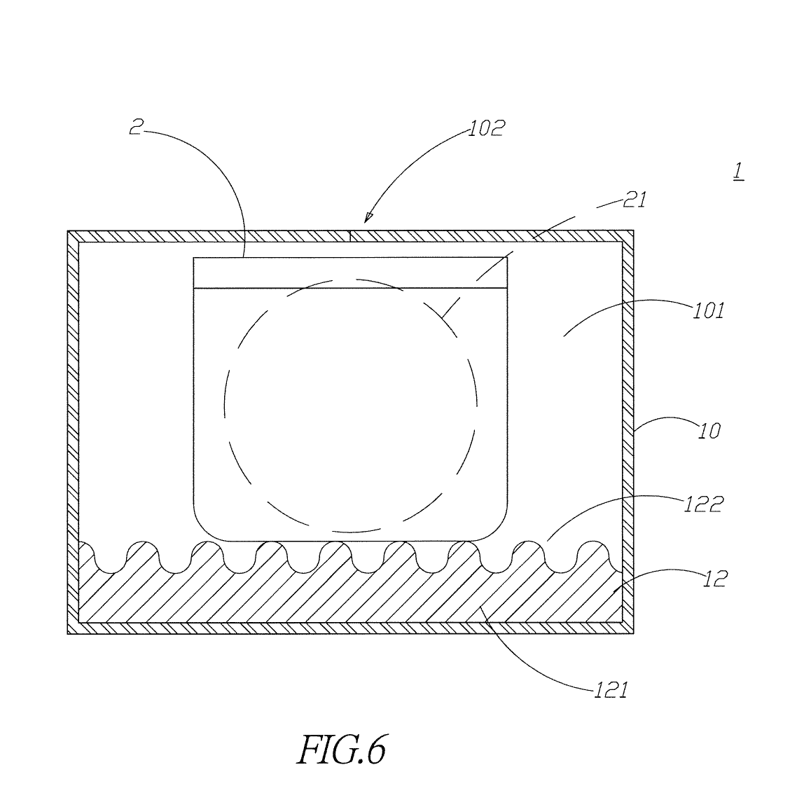

Refer to FIG. 4, a further embodiment of the present invention is revealed. The difference between this embodiment and the first embodiment is in that both the first surface 121 and the second surface 122 of the buffer pad 12 in the first embodiment are flat surfaces (as shown in FIG. 2) while the first surface 121 of the buffer pad 12 of this embodiment is a patterned surface formed by a plurality of geometric patterns 1211. The geometric patterns can be wave-like patterns, watermark patterns, or pyramid like shapes. Thus the contact area between the buffer pad 12 and the package box 10 is reduced and the vibration transmitted to the substrate storage container 2 is further reduced so as to prevent the at least one substrate 21 in the substrate storage container 2 from rotating, having friction with components inside the substrate storage container 2 and further producing contaminating particles in the substrate storage container 2. As shown in FIG. 5, surfaces of the buffer pad 12 in contact with the package box 10 are also patterned surfaces for reducing contact area between the buffer pad 12 and the package box 10. Or only the second surface 122 of the buffer pad 12 is a patterned surface for reducing contact area between the buffer pad 12 and the substrate storage container 2, as shown in FIG. 6. Both embodiments achieve the same effect as the above embodiment. Or both the first surface 121 and the second surface 122 of the buffer pad 12 are patterned surfaces so as to reduce the contact area between the buffer pad 12 and the package box 10/the substrate storage container 2 at the same time.

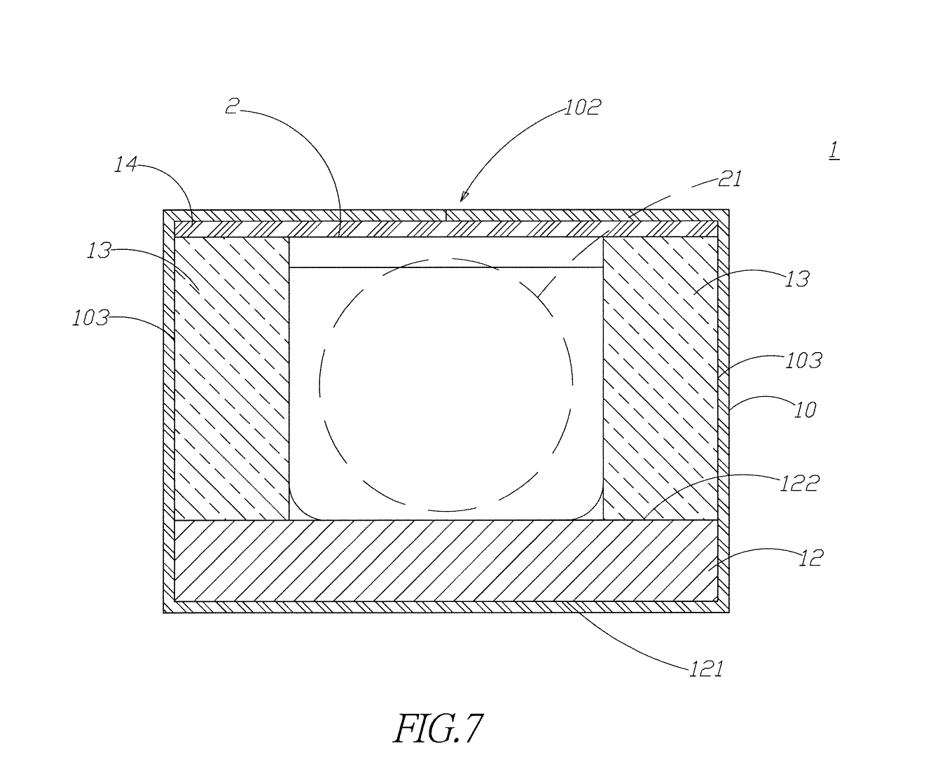

Refer to FIG. 7, a further embodiment is revealed. The difference between this embodiment and the first embodiment is in that the package structure 1 of this embodiment further includes a side buffer pad 13 arranged at side walls 103 of the package box 10 and covering a periphery of the substrate storage container 2 for preventing the substrate storage container 2 from moving on the second surface 122 of the buffer pad 12 and colliding with the side walls 103 of the package box 10. Moreover, the side buffer pad 13 also prevents the substrate storage container 2 from contacting with the side walls 103 of the package box 10 directly. Thus vibration generated outside the package structure 1 will not be transmitted to the substrate storage container 2 through the side buffer pad 13. The density of the side buffer pad 13 is below 70 kg/m³. In this embodiment, the package structure 1 further includes a protection pad 14 that covers on top of the substrate storage container 2 for preventing the top of the substrate storage container 2 from bumping into the package box 10 and causing damages of the substrate storage container 2.

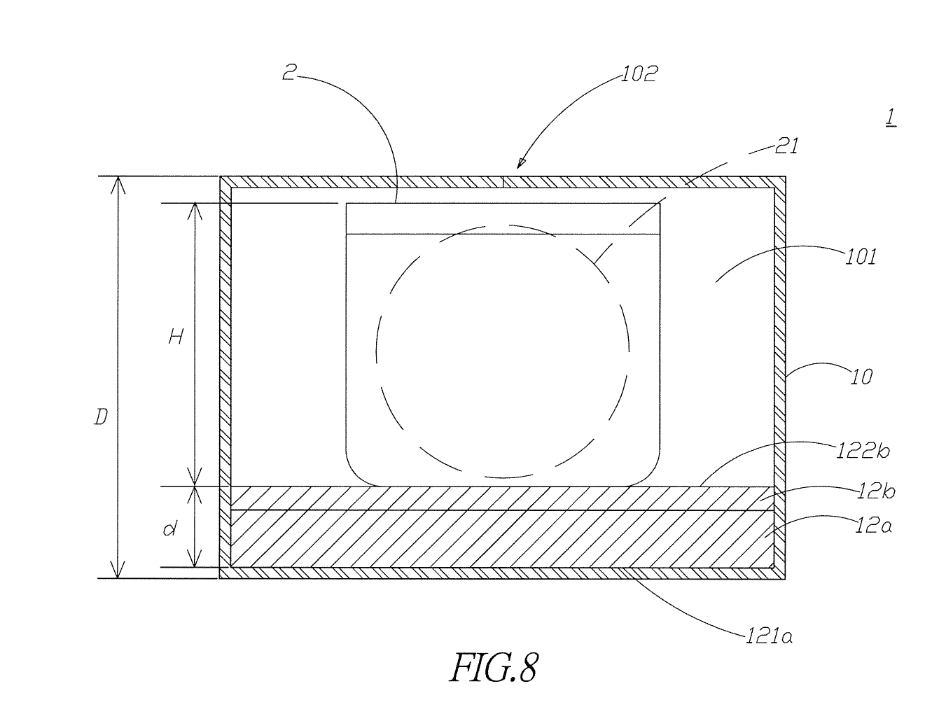

Refer to FIG. 8, the difference between this embodiment and the first embodiment is in that this embodiment includes a plurality of buffer pads 12 arranged in the package box 10. The buffer pads 12 are stacked from the bottom of the package box 10 up to the top. In this embodiment, the package structure consists of a first buffer pad 12a and a second bugger pad 12b. The first buffer pad 12a has a first surface 121a in contact with the bottom of the package box 10 while the second buffer pad 12b is disposed over the first buffer pad 12a and having a second surface 122b used for loading the substrate storage container 2. The maximum thickness of the first buffer pad 12a and the second buffer pad 12b is equal to the difference between a depth D of the package box 10 and a vertical height H of the substrate storage container 2. Moreover, the total thickness d of the first buffer pad 12a and the second buffer pad 12b is determined according to the vertical height H of the substrate storage container 2. The ratio of the vertical height H of the substrate storage container 2 to the total thickness d of the first buffer pad 12a and the second buffer pad 12b is ranging from 1 to 50. Thus the vertical height H of the substrate storage container 2 is 486 mm and the minimum total thickness of the first buffer pad 12a and the second buffer pad 12b is about 9.7 mm.

The density of the first buffer pad 12a and the density of the second buffer pad 12b are both below 70 kg/m³. Their densities can be the same or different from each other. When the density of the first buffer pad 12a is different from the density of the second buffer pad 12b, the vibration generated outside the package structure 1 and transmitted to the substrate storage container 2 is minimized effectively.

The receiving slot 123 of the second embodiment can be applied to the second surface 122b of the second buffer pad 12b in this embodiment. The patterned surface of the third embodiment can also be applied to the first surface 121a of the first buffer pad 12a of this embodiment. Or the side buffer pad 13 and the protection pad 14 of the fourth embodiment is applied to package box 10 of this embodiment. All the above applications can effectively reduce the vibration transmitted to the substrate storage container 2.

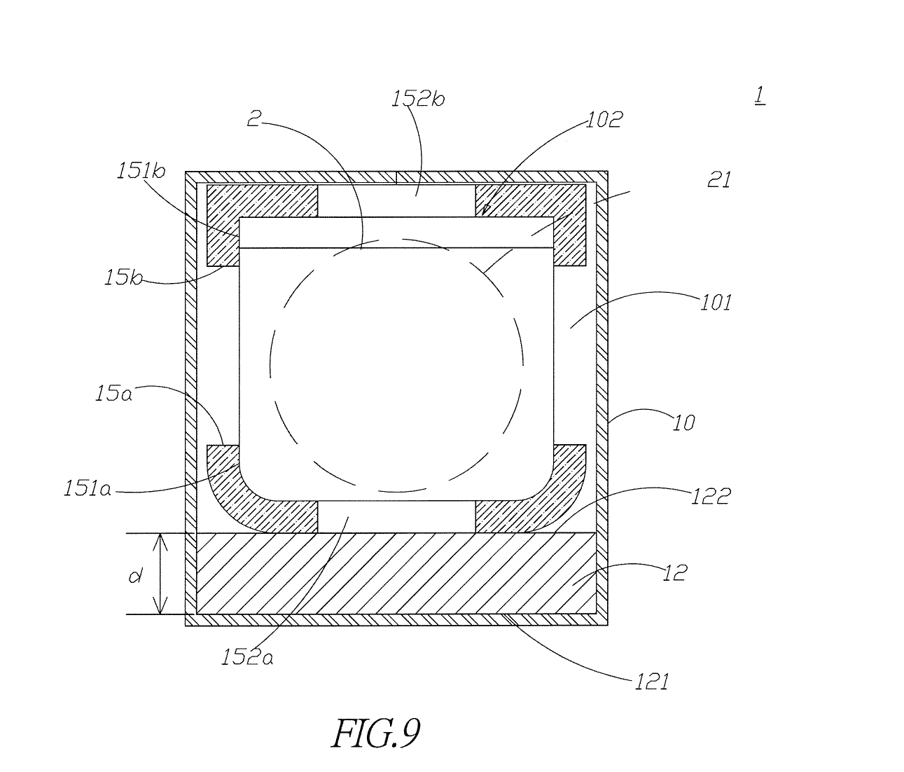

Refer to FIG. 9, the difference between this embodiment and the above one is in that the package structure 1 of this embodiment further includes a first crash pad 15a and a second crash pad 15b. The first crash pad 15a is disposed on a second surface 122 of a buffer pad 12. The first crash pad 15a has a first receiving slot 151a and a bottom of a substrate storage container 2 is loaded in the first receiving slot 151a. The second crash pad 15b is arranged at the top of the substrate storage container 2, corresponding to the first crash pad 15a and located inside a receiving space 101 of a package box 10. The second crash pad 15b also has a second receiving slot 151b for mounting the top of the substrate storage container 2.

Both the first crash pad 15a and the second crash pad 15b are used to prevent the substrate storage container 2 from moving in the receiving space 101 of the package box 10 and colliding with the package box 10. Thus the substrate 21 stored in the substrate storage container 2 will not be damaged due to impact. Moreover, the periphery of the first crash pad 15a and the periphery of the second crash pad 15b are not in direct contact with side walls 103 of the package box 10 so as to prevent the vibration outside the package structure 1 from being transmitted to the substrate storage container 2 through the first crash pad 15a or the second crash pad 15b. As to the buffer pad 12, it also prevents the first crash pad 15a from sliding on the second surface 122.

In this embodiment, the first receiving slot 151a of the first crash pad 15a and the second receiving slot 151b of the second crash pad 15b respectively include at least one first hollow part 152a and at least one second hollow part 152b. Thus the contact area between the substrate storage container 2 and the first crash pad 15a and the contact area between the substrate storage container 2 and the second crash pad 15b are reduced so as to reduce the vibration transmitted to the substrate storage container 2.

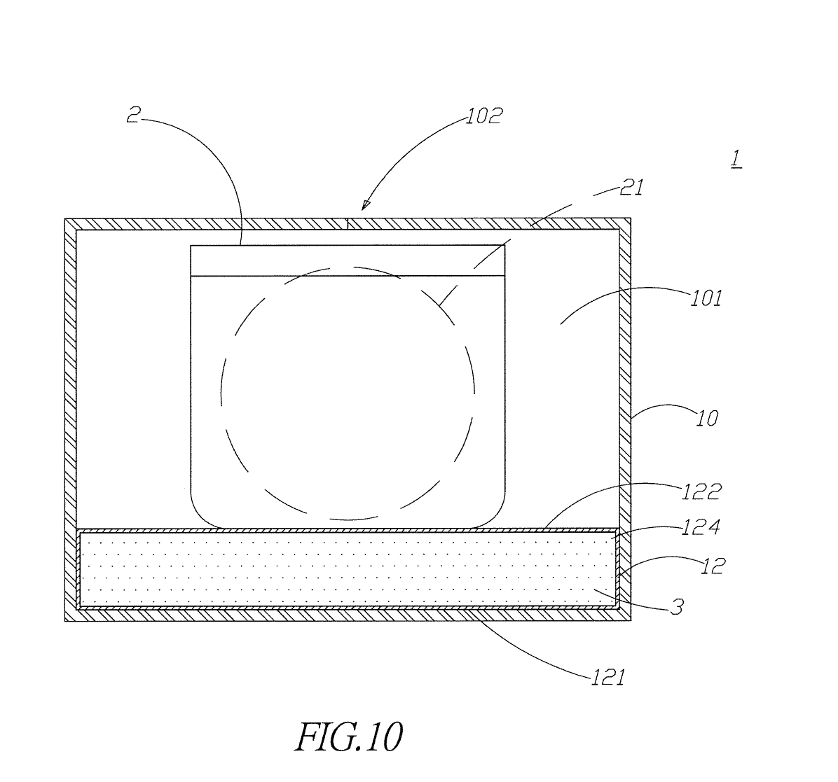

Refer to FIG. 10, a further embodiment is revealed. As shown in the figure, the difference between this embodiment and the first one is in that the buffer pad of this embodiment is not made from solid materials. In this embodiment, the buffer pad 12 includes a filling space 124. Users can fill a fluid 3 such as gas or liquid into the filling space 124. Thus the buffer pad 12 of this embodiment can also absorb vibration transmitted from the outside of the package structure 1 and further reduce the amount of the vibration transmitted to the substrate storage container 2.

In summary, the package structure of the present invention is applied to pack a substrate storage container (such as the front opening unified pod). The package structure includes a package box and at least one buffer pad disposed on the package box. The substrate storage container is arranged at the buffer pad. By the buffer pad that separates the package box from the substrate storage container, vibration generated outside the package structure will not be directly transmitted to the substrate storage container. This prevents the at least one substrate stored in the substrate storage container from rotating and further avoids friction between the rotating substrate and internal components of the substrate storage container. Thus the amount of contaminating particles generated due to rotation of the substrate during transportation is reduced dramatically.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A package structure for substrate storage containers comprising:
a package box having an opening and a receiving space communicating with the opening; and
at least one buffer pad disposed on the package box and located in the receiving space; a substrate storage container is arranged at the buffer pad and a density of the buffer pad is smaller than 70 kg/m³.

2. The package structure as claimed in claim 1, wherein total thickness of the buffer pad is determined according to a vertical height of the substrate storage container; a ratio of the vertical height of the substrate storage container to the total thickness of the buffer pad is ranging from 1 to 50.

3. The package structure as claimed in claim 1, wherein the buffer pad includes a first surface and a second surface; the first surface is in contact with the package box while the second surface is disposed with the substrate storage container.

4. The package structure as claimed in claim 3, wherein at least one of the first surface and the second surface is a flat surface.

5. The package structure as claimed in claim 3, wherein at least one of the first surface and the second surface is a patterned surface; the patterned surface includes a plurality of geometric patterns; the geometric pattern is selected from the group consisting of a wave-like pattern, a watermark pattern, and a pyramid like shape.

6. The package structure as claimed in claim 3, wherein the second surface of the buffer pad further includes a receiving slot for mounting the substrate storage container.

7. The package structure as claimed in claim 1, wherein a surface of the buffer pad in contact with the package box is a patterned surface including a plurality of geometric patterns; the geometric pattern is selected from the group consisting of a wave-like pattern, a watermark pattern, and a pyramid like shape.

8. The package structure as claimed in claim 1, wherein the package structure for substrate storage containers further includes:
at least one side buffer pad arranged in the package box and covering a periphery of the substrate storage container.

9. The package structure as claimed in claim 1, wherein the package structure for substrate storage containers further includes:
a first crash pad that is disposed on a surface of the substrate storage container in contact with the buffer pad and is arranged at the buffer pad.

10. The package structure as claimed in claim 9, wherein the first crash pad includes a first receiving slot and the substrate storage container is arranged at the first receiving slot.

11. The package structure as claimed in claim 10, wherein the first receiving slot of the first crash pad includes at least one first hollow part.

12. The package structure as claimed in claim 9, wherein the package structure for substrate storage containers further includes a second crash pad arranged at the substrate storage container, corresponding to the first crash pad, and located in the receiving space.

13. The package structure as claimed in claim 12, wherein the second crash pad includes a second receiving slot and the substrate storage container is disposed on the second receiving slot.

14. The package structure as claimed in claim 13, wherein the second receiving slot of the second crash pad includes at least one second hollow part.

15. The package structure as claimed in claim 1, wherein the package structure for substrate storage containers further includes:
a protection pad covering the substrate storage container and located in the receiving space.

16. A package structure for substrate storage containers comprising:
a package box having an opening and a receiving space communicating with the opening; and
at least one buffer pad disposed on the package box, located in the receiving space, and being disposed with a substrate storage container; the buffer pad having a filling space for receiving a fluid therein.
